(19) United States
(12) Patent Application Publication
(10) Pub. No.: US 2011/0309872 A1
(43) Pub. Date: Dec. 22, 2011

(54) Voltage Spike Protection for Power DMOS Devices

(76) Inventors: Cynthia Blair, Morgan Hill, CA (US); Helmut Brech, Mintraching (DE)

(21) Appl. No.: 12/817,869

(22) Filed: Jun. 17, 2010

(51) Int. Cl. H03L 5/00; H05K 3/30

(52) U.S. Cl. 327/321; 29/832

(57) ABSTRACT

A power device includes a power transistor, a capacitor with a first plate coupled to a ground node and a second plate separated from the first plate by an insulator, a first plurality of wires coupling a drain node of the power transistor to the second plate of the capacitor, a second plurality of wires coupling the second plate of the capacitor to a DC supply node, and a voltage clamping device coupled in parallel with the capacitor. The voltage clamping device is operable to limit the voltage at the second plate of the capacitor to a value below a breakdown voltage of the power transistor.

### BACKGROUND

The breakdown voltage of a DMOS (double-diffused metal-oxide-semiconductor) power device such as an LDMOS (laterally diffused metal oxide semiconductor) transistor can range from about 50V to 60V to several hundred volts (e.g., 100V to 200V) depending on the technology used to fabricate the device. When a large amount of current flows in a DMOS device for drain voltages above the breakdown voltage, it is possible to turn on the parasitic NPN bipolar device. This is an undesired effect and the condition is typically referred to as avalanche breakdown. Avalanche breakdown can destroy power DMOS devices.

The instantaneous voltage spike that appears at the drain of a DMOS power transistor is given by:

V_{SPIKE}=L×di/dt (1)

The inductance L is a function of the number and type of external wire, inductor or micro-strip connections to the package including the DMOS device and the number and type of internal wire connections from the package to the drain of the power transistor. (DC feed line and LF termination) The inductance L in equation (1) is typically about 10 nH to 20 nH or greater, depending on the application. Techniques have been used to lower the inductance seen at the drain of DMOS device. For example, the DC feed lines to the drain of DMOS devices can be widened to increase resonance and reduce inductance. Also, terminations can be provided on a ¼ wave feed line for providing DC bias. Each of these techniques can provide some improvement in voltage spike protection, but current state of the art practices are approaching practical and theoretical limits which are difficult to overcome. In addition, certain techniques such as providing terminations on a ¼ wave DC feed line with no RF or baseband ground can negatively impact power device linearity. Smart discrete packaging methodologies can be used to further reduce inductance in these DC feed lines, but market trends point to limits soon being reached with this technology as well.

Further exasperating voltage spike conditions at the drain of DMOS power devices is the ever-increasing demand for higher signal bandwidth. Many applications, particularly wireless communication applications have high bandwidth requirements. Higher clock speeds are needed to meet demand for wider DMOS signal bandwidths. However, higher clock speeds increase the portion of V_{SPIKE} related to di/dt in equation (1). For example, DMOS output signals change state in 4 ns for a 250 MHz clock rate. As these speeds increase, these and other conditions can cause voltage spike conditions at the drain of DMOS devices which reach several hundred volts, far exceeding the breakdown voltage capability of the devices and thus causing damage.

### SUMMARY

According to an embodiment of a voltage clamping circuit for coupling to a power device, the voltage clamping circuit includes a voltage clamping device and the power device includes an output match network coupled to an output node of a power transistor. The output match networking includes a capacitor with a first plate coupled to a ground node and a second plate separated from the first plate by an insulator, a first plurality of electrical conductors coupling the output node of the power transistor to the second plate of the capacitor and a second plurality of electrical conductors coupling the second plate of the capacitor to a DC supply node. The voltage clamping device is coupled in parallel with the capacitor and is operable to limit the voltage at the second plate of the capacitor to a value below a breakdown voltage of the power transistor. According to an embodiment of a method for suppressing voltage spikes at the power device, the method includes coupling the voltage clamping device in parallel with the capacitor and operating the voltage clamping device in a conducting state to limit the voltage at the second plate of the capacitor to a value below a breakdown voltage of the power transistor.

According to an embodiment of a method for manufacturing a power device, the method includes providing a power transistor, providing a capacitor with a first plate coupled to a ground node and a second plate separated from the first plate by an insulator, coupling a drain node of the power transistor to the second plate of the capacitor, coupling the second plate of the capacitor to a DC supply node and coupling a voltage clamping device in parallel with the capacitor. The voltage clamping device is operable to limit the voltage at the second plate of the capacitor to a value below a breakdown voltage of the power transistor. The DC supply node is a virtual ground at baseband and RF, providing an environment where the clamp device can operate without adversely impacting device linearity.

According to an embodiment of a power device, the device includes a power transistor, a capacitor with a first plate coupled to a ground node and a second plate separated from the first plate by an insulator, a first plurality of wires coupling a drain node of the power transistor to the second plate of the capacitor, a second plurality of wires coupling the second plate of the capacitor to a DC supply node, and a voltage clamping device coupled in parallel with the capacitor. The voltage clamping device is operable to limit the voltage at the second plate of the capacitor to a value below a breakdown voltage of the power transistor.

According to an embodiment of an integrated voltage clamping device, the device includes a first capacitor plate formed from an electrically conductive material arranged on a bottom side of a semiconductor substrate, a second capacitor plate formed from an electrically conductive material arranged above a top side of the semiconductor substrate and a voltage clamping device. The voltage clamping device has a first node coupled to the electrically conductive material arranged on the bottom side of the semiconductor substrate and a second node connected to the electrically conductive material arranged above the top side of the semiconductor substrate. The voltage clamping device is operable to clamp the voltage at the second capacitor plate to a predetermined voltage.

Those skilled in the art will recognize additional features and advantages upon reading the following detailed description, and upon viewing the accompanying drawings.

### BRIEF DESCRIPTION OF THE DRAWINGS

FIG. 1 is a circuit diagram of an embodiment of a voltage clamping circuit coupled to a power device.

FIG. 2 is a circuit diagram of an embodiment of a zener diode coupled to a power device.

FIG. 3 is a block diagram of an embodiment of a package including a voltage clamping circuit coupled to a power device.

### DETAILED DESCRIPTION

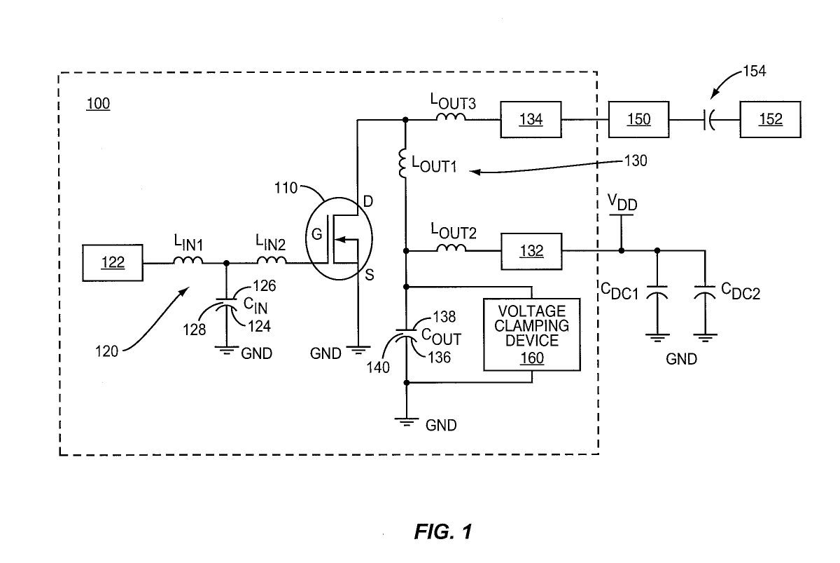

FIG. 1 illustrates a circuit diagram of a power device 100 including a power transistor 110. An input match network 120 is coupled between an input terminal 122 of the power device 100 and the gate (G) of the power transistor 110. The input match network 120 includes a DC blocking capacitor C_{IN} with a first plate 124 separated from a second plate 126 by an insulator 128. A first conductive branch L_{IN1} of the input match network 120 connects the input terminal 122 of the power device 100 to the second plate 126 of C_{IN}. A second conductive branch L_{IN2} of the input match network 120 connects the second plate 126 of C_{IN} to the gate of the power transistor 110. The first plate 124 of C_{IN} is coupled to a ground node (GND). The conductive branches of the input match network 120 can be implemented as bond wires, ribbons, etc. The capacitors of the input match network 120 can be implemented as discrete components separate from the power transistor 110 or can be integrated with the power transistor 110 on the same die. The input match network 120 can have other configurations which are within the scope of the invention.

An output match network 130 is coupled between the drain (D) of the power transistor 110 and a DC feed/baseband termination terminal 132 of the power device 100 and an RF/baseband output terminal 134 of the power device 100. The output match network 130 includes a DC blocking capacitor C_{OUT} with a first plate 136 separated from a second plate 138 by an insulator 140. A first conductive branch L_{OUT1} of the output match network 130 connects the drain of the power transistor 110 to the second plate 138 of C_{OUT}. A second conductive branch L_{OUT2} of the output match network 130 connects the second plate 138 of C_{OUT} to the DC feed/baseband termination terminal 132 of the power device 100. The first plate 136 of C_{OUT} is coupled to a ground node (GND), thus providing an RF/baseband ‘cold point’ path to ground between L_{OUT1} and L_{OUT2}. A third conductive branch L_{OUT3} of the output match network 130 connects the drain of the power transistor 110 to the RF/output terminal 134 of the power device 100. The source (S) of the power transistor 110 is coupled to a ground node (GND).

The conductive branches of the output match network 130 can be implemented as bond wires, ribbons, etc. The capacitors of the output match network 130 can be implemented as discrete components separate from the power transistor 110 or can be integrated with the power transistor 110 on the same die. The output match network 130 can have other configurations which are within the scope of the invention.

The power transistor 110 can be any type of MOS power transistor such as a DMOS or LDMOS transistor, and more generally any type of RF device susceptible to breakdown. The power device 100 can be included in a package as indicated by the dashed line shown in FIG. 1. External terminals 150 and 152 and capacitor(s) 154 can be coupled to the RF output terminal 134 of the power device 100 for coupling to the output of the power device 100. DC bias (V_{DD}) is applied at the DC feed/baseband termination terminal 132 of the power device 100 for ensuring proper biasing of the power transistor 110. DC blocking capacitors C_{DC1} and C_{DC2} can be externally coupled to the DC feed/baseband termination terminal 132 of the power device 100. The DC feed/baseband termination terminal 132 provides a point that is “cold”, that is terminated/virtually grounded at baseband and RF via the capacitor C_{OUT}. Voltage spikes periodically arise along the DC feed path from the DC feed/baseband termination terminal 132 to the drain of the power transistor 110. The magnitude of the voltage spikes at the drain of the power transistor 110 is given by equation (1).

The voltage spikes at the drain of the power transistor 110 are limited by a voltage clamping device 160 coupled in parallel with the DC blocking capacitor C_{OUT} of the output match network 130. The voltage clamping device 160 limits the voltage at the second plate 138 of C_{OUT} to a value below the breakdown voltage of the power transistor 110. The voltage clamping device 160 enters a conducting state responsive to the voltage at the second plate 138 of C_{OUT} rising above a predetermined voltage smaller than the breakdown voltage of the power transistor 110 so that the voltage at the second plate 138 of C_{OUT} is clamped approximately to the predetermined voltage. Accordingly, the maximum voltage at the drain of the power transistor 110 is the clamp voltage of the voltage clamping device 160 plus the magnitude of the voltage spike across the first conductive branch L_{OUT1} of the output match network 130. The clamp voltage of the voltage clamping device 160 can be selected so that the clamp voltage plus the voltage across L_{OUT1} does not exceed the breakdown voltage of the power transistor 110, ensuring the power transistor 110 does not enter a parasitic avalanche breakdown condition. In one embodiment, the predetermined voltage is greater than a minimum operating voltage of the power transistor 110 and less than the breakdown voltage of the power transistor 110.

The voltage clamping device 160 is provided near the drain of the power transistor 110 at the RF/baseband cold point between L_{OUT1} and L_{OUT2} of the output match network 130, and thus maintains power device linearity while clamping voltage spikes as close as possible to the drain of the power transistor 110 without adversely affecting transistor performance. Coupling the voltage clamping device 160 in parallel with output match capacitor C_{OUT} in effect reduces the inductance term L in equation (1) to the inductance associated with the first conductive branch L_{OUT1} of the output match network 130. Voltage spikes which arise between the DC feed/baseband termination terminal 132 and the second plate 138 of C_{OUT} are clamped by the voltage clamping device 160, and thus are not seen at the drain of the power transistor 110. Only voltage spikes which occur across the first conductive branch L_{OUT1} of the output match network 130 are seen at the transistor drain. All other voltage spikes along the DC feed path to the power transistor drain are clamped to a voltage below the breakdown voltage of the power transistor 110 by the voltage clamping device 160. As such, the magnitude of voltage spikes at the drain of the power transistor 110 is given by:

V_{SPIKE}_{_{—}}_{DRAIN}=L₁×di/dt+V_{CLAMP} (2)

where L₁ represents the inductance of L_{OUT1} and V_{CLAMP} is the clamping voltage of the voltage clamping device 160.

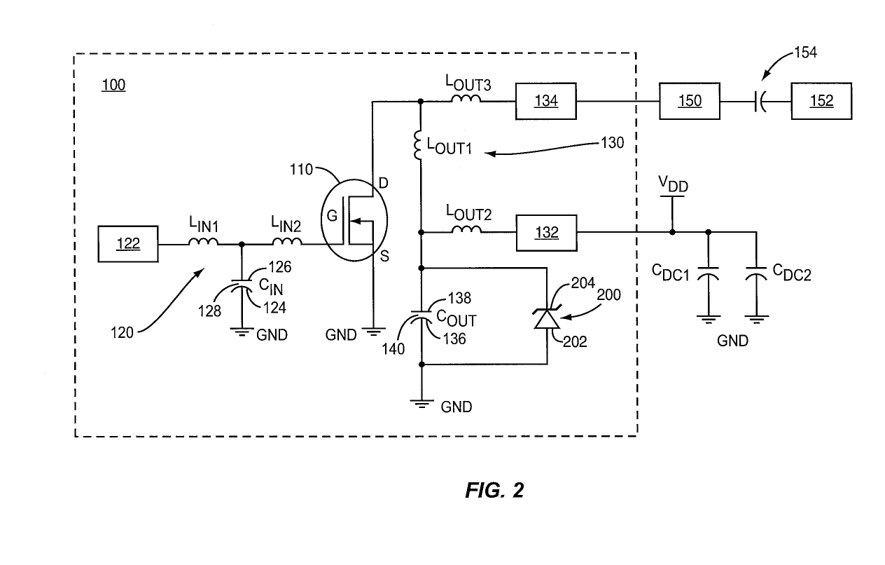

FIG. 2 illustrates a circuit diagram of an embodiment of the power device 100 where the voltage clamping device is a zener diode 200 coupled in parallel with the capacitor C_{OUT} of the output match network 130. The zener diode 200 can be physically implemented as a single zener diode or a plurality of zener diodes coupled in parallel with C_{OUT}. The anode terminal 202 of the zener diode 200 is electrically coupled to the first plate 136 of C_{OUT} and the cathode terminal 204 of the diode 200 is electrically coupled to the second plate 138 of C_{OUT}. A plurality of resistors can also be coupled in parallel with C_{OUT} and the zener diode 200. According to an embodiment, the resistors have a total parallel resistance of about 1 MΩ or more between the plates of C_{OUT}. Providing resistors in parallel with C_{OUT} and the zener diode 200 can be particularly beneficial when C_{OUT} is leaky, where a leaky capacitor in the output match network 130 enhances the ruggedness of the power device 100. In each case, the zener diode 200 limits the voltage at 138 C_{OUT} to a value below a breakdown voltage of the power transistor 110, ensuring the power transistor 110 does not enter parasitic avalanche breakdown.

The zener diode 200 enters a conducting state responsive to the voltage at the second plate 138 of C_{OUT} rising above the reverse breakdown voltage of the zener diode 200, which is below the breakdown voltage of the power transistor 110. Accordingly, the power transistor 110 does not enter an avalanche breakdown condition in the presence of large voltage spikes along the DC bias feed path which occur during high speed switching of the power transistor 110. The particular breakdown voltage of the zener diode 200 depends on the type of application in which the power device 100 is used. Broadly, the breakdown voltage of the zener diode 200 is selected so that the voltage across the first conductive branch L_{OUT1} of the output match network 130 plus the breakdown voltage of the zener diode 200 does not exceed the breakdown voltage of the power transistor 110. This ensures the power transistor 110 does not enter an avalanche breakdown condition. Choosing the breakdown voltage of the zener diode 200 is a function of several variables, including but not limited to switching speed of the power device 100, the inductance of L_{OUT1} and the breakdown voltage of the power transistor 110.

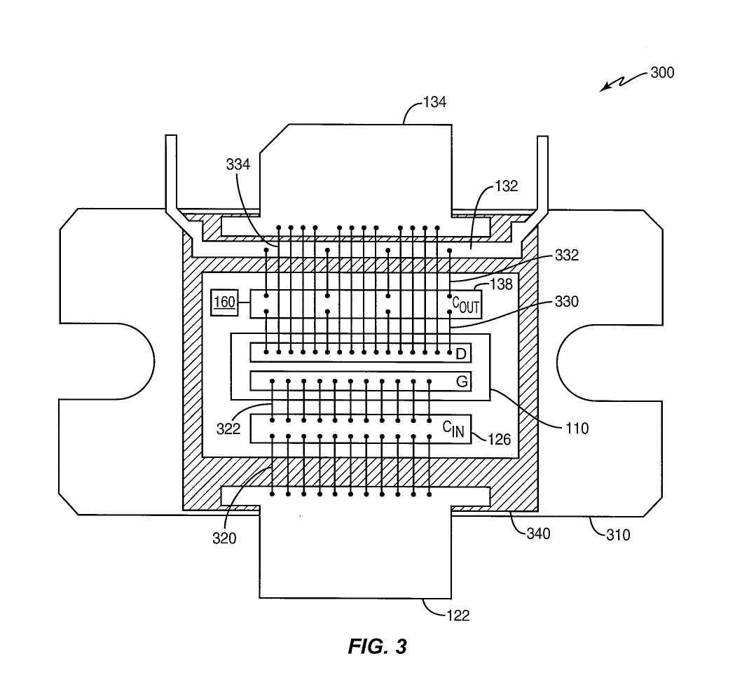

FIG. 3 illustrates a top-down plan view of an embodiment of a package 300 including the power transistor 110 and the voltage clamping device 160. The package 300 includes a thermally and electrically conductive flange 310 on which the power transistor 110, the voltage clamping device 160 and the respective capacitors C_{IN} and C_{OUT} of the input and output match networks 120 and 130 are attached. On the input side, the first conductive branch I_{IN1} of the input match network 120 includes a plurality of parallel bond wires 320 which connect the input terminal 122 of the power device 100 to the second plate 126 of C_{IN}. The second conductive branch L_{IN2} of the input match network 120 similarly includes a plurality of parallel bond wires 322 which connect the second plate 126 of C_{IN} to the gate terminal (G) of the power transistor 110.

The first conductive branch L_{OUT1} of the output match network 130 includes a plurality of parallel bond wires 330 which connect the drain terminal (D) of the power transistor 110 to the second plate 138 of C_{OOUT}. The second conductive branch L_{OUT2} of the output match network 130 similarly includes a plurality of parallel bond wires 332 which connect the second plate 138 of C_{OUT} to the DC feed/baseband termination terminal 132 of the power device 100. The third conductive branch L_{OUT3} of the output match network 130 includes a plurality of parallel bond wires 334 which connect the drain terminal of the power transistor 110 to the RF output terminal 134 of the power device 100. The source terminal which is on the bottom side of the power transistor 110 is connected to the conductive flange 310. The first plate 136 of C_{OUT} of the output match network 130 and the first plate 126 of C_{IN} of the input match network 120 are likewise connected to the conductive flange 310, which can be grounded. The terminals 122, 132 and 134 of the power device 110 are mounted on an insulative member 340 attached to the conductive flange 310.

In some embodiments, the total inductance of the L_{OUT1} bond wires 330, e.g., can be between about 100 pH to 200 pH whereas the total inductance from the drain (D) of the power transistor 110 to the DC feed/baseband termination terminal 132 can be about 3 nH to 4 nH with relatively large capacitors to the DC feed/baseband termination terminal 132 of the power device 100. As such, voltage spikes across LOUT1 are relatively small compared to voltage spikes across LOUT2 and at the DC feed/baseband termination terminal 132. By clamping voltage spikes arising between the second plate 138 of COUT and the DC feed/baseband termination terminal 132 of the power device 100, a 10× voltage protection improvement results. Of course, other results are possible depending on, e.g., the inductance of the L_{OUT1} bond wires 330, the inductance of the L_{OUT2} bond wires 332, the inductance of the DC feed/baseband termination terminal 132, the switching speed of the power transistor 110, etc. In each case, the clamping voltage of the voltage clamping device 160 is determined so that the voltage across L_{OUT1} of the output match network 130 plus the clamping voltage of the voltage clamping device 160 does not exceed the breakdown voltage of the power transistor 110, ensuring the power transistor 110 does not enter an avalanche breakdown condition. The voltage clamping device 160 can be a zener diode as described previously herein with an anode terminal electrically connected the conductive flange 310 and a cathode terminal electrically connected to the second plate 138 of C_{OUT}, or another type of clamping device such as an FET (filed effect transistor) coupled in parallel with C_{OUT}. FIG. 3 shows the power transistor 110 and the capacitor C_{OUT} of the output match network 130 provided on separate semiconductor dies. However, the power transistor 110 and C_{OUT} can be integrated on the same semiconductor die. The voltage clamping device 160 and C_{OUT} can also be integrated on the same semiconductor die

Spatially relative terms such as “under”, “below”, “lower”, “over”, “upper” and the like, are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A voltage clamping circuit for coupling to a power device with an output match network coupled to an output node of a power transistor, the output match networking including a capacitor with a first plate coupled to a ground node and a second plate separated from the first plate by an insulator, a first plurality of electrical conductors coupling the output node of the power transistor to the second plate of the capacitor and a second plurality of electrical conductors coupling the second plate of the capacitor to a DC supply node, the DC supply node being virtually grounded at baseband and RF via the capacitor, the voltage clamping circuit comprising a voltage clamping device coupled in parallel with the capacitor, the voltage clamping device operable to limit the voltage at the second plate of the capacitor to a value below a breakdown voltage of the power transistor.

2. A voltage clamping circuit according to claim 1, wherein the voltage clamping device is operable to enter a conducting state responsive to the voltage at the second plate of the capacitor rising above a predetermined voltage smaller than the breakdown voltage of the power transistor so that the voltage at the second plate of the capacitor is clamped approximately to the predetermined voltage.

3. A voltage clamping circuit according to claim 2, wherein the predetermined voltage is greater than a minimum operating voltage of the power transistor and less than the breakdown voltage of the power transistor.

4. A voltage clamping circuit according to claim 1, wherein the voltage clamping device comprises a zener diode with a reverse breakdown voltage below the breakdown voltage of the power transistor.

5. A voltage clamping circuit according to claim 1, wherein the voltage clamping device comprises a plurality of zener diodes coupled in parallel with the capacitor.

6. A voltage clamping circuit according to claim 5, wherein the voltage clamping device further comprises a plurality of resistors coupled in parallel with the capacitor and the plurality of zener diodes.

7. A voltage clamping circuit according to claim 6, wherein the plurality of resistors has a total parallel resistance of about 1 MΩ or more.

8. A method of suppressing voltage spikes at a power device with an output match network coupled to an output node of a power transistor, the output match networking including a capacitor with a first plate coupled to a ground node and a second plate separated from the first plate by an insulator, a first plurality of electrical conductors coupling the output node of the power transistor to the second plate of the capacitor and a second plurality of electrical conductors coupling the second plate of the capacitor to a DC supply node, the DC supply node being virtually grounded at baseband and RF via the capacitor, the method comprising:
coupling a voltage clamping device in parallel with the capacitor; and
operating the voltage clamping device in a conducting state to limit the voltage at the second plate of the capacitor to a value below a breakdown voltage of the power transistor.

9. A method according to claim 8, comprising operating the voltage clamping device in the conducting state responsive to the voltage at the second plate of the capacitor rising above a predetermined voltage smaller than the breakdown voltage of the power transistor so that the voltage at the second plate of the capacitor is clamped approximately to the predetermined voltage.

10. A method according to claim 9, wherein the predetermined voltage is greater than a minimum operating voltage of the power transistor and less than the breakdown voltage of the power transistor.

11. A method according to claim 8, wherein coupling a voltage clamping device in parallel with the capacitor comprises coupling a zener diode in parallel with the capacitor.

12. A method according to claim 8, wherein coupling a voltage clamping device in parallel with the capacitor comprises coupling a plurality of zener diodes in parallel with the capacitor.

13. A method according to claim 12, further comprising coupling a plurality of resistors in parallel with the capacitor and the plurality of zener diodes.

14. A power device, comprising:
a power transistor;
a capacitor with a first plate coupled to a ground node and a second plate separated from the first plate by an insulator;
a first plurality of wires coupling a drain node of the power transistor to the second plate of the capacitor;
a second plurality of wires coupling the second plate of the capacitor to a DC supply node; and
a voltage clamping device coupled in parallel with the capacitor, the voltage clamping device operable to limit the voltage at the second plate of the capacitor to a value below a breakdown voltage of the power transistor.

15. A power device according to claim 14, wherein the power transistor is an LDMOS transistor.

16. A power device according to claim 14, wherein a total inductance of the first plurality of wires is between about 100 pH to 200 pH.

17. A power device according to claim 14, wherein the power transistor is included in a package and the first and second plurality of wires are bond wires.

18. A power device according to claim 14, wherein the power transistor and the capacitor are integrated on the same semiconductor die.

19. A power device according to claim 18, wherein the first plate of the capacitor comprises an electrically conductive material arranged on a bottom side of a semiconductor substrate of the die, the second plate of the capacitor comprises an electrically conductive material arranged above a top side of the semiconductor substrate, and the voltage clamping device comprises a zener diode with an anode terminal connected to the electrically conductive material arranged on the bottom side of the semiconductor substrate and a cathode terminal connected to the electrically conductive material arranged above the top side of the semiconductor substrate.

20. A method of manufacturing a power device, comprising:
providing a power transistor;
providing a capacitor with a first plate coupled to a ground node and a second plate separated from the first plate by an insulator;
coupling a drain node of the power transistor to the second plate of the capacitor;
coupling the second plate of the capacitor to a DC supply node; and
coupling a voltage clamping device in parallel with the capacitor, the voltage clamping device operable to limit the voltage at the second plate of the capacitor to a value below a breakdown voltage of the power transistor.

21. A method according to claim 20, further comprising mounting the power transistor to a package, and wherein the drain node of the power transistor is coupled to the second plate of the capacitor via a first plurality of bond wires and the second plate of the capacitor is coupled to the DC supply node via a second plurality of bond wires.

22. A method according to claim 20, wherein the power transistor and the capacitor are integrated on the same semiconductor die.

23. A method according to claim 22, comprising:
arranging an electrically conductive material on a bottom side of a semiconductor substrate of the semiconductor die to form the first plate of the capacitor;
arranging an electrically conductive material above a top side of the semiconductor substrate to form the second plate of the capacitor; and
coupling an anode terminal of a zener diode to the electrically conductive material arranged on the bottom side of the semiconductor substrate and a cathode terminal of the zener diode to the electrically conductive material arranged above the top side of the semiconductor substrate, the voltage clamping device comprising the zener diode.

24. An integrated voltage clamping device, comprising:
a first capacitor plate formed from an electrically conductive material arranged on a bottom side of a semiconductor substrate;
a second capacitor plate formed from an electrically conductive material arranged above a top side of the semiconductor substrate; and
a voltage clamping device having a first node coupled to the electrically conductive material arranged on the bottom side of the semiconductor substrate and a second node connected to the electrically conductive material arranged above the top side of the semiconductor substrate, the voltage clamping device operable to clamp the voltage at the second capacitor plate to a predetermined voltage.

25. An integrated voltage clamping device according to claim 24, wherein the voltage clamping device comprises a zener diode with an anode terminal connected to the electrically conductive material arranged on the bottom side of the semiconductor substrate and a cathode terminal connected to the electrically conductive material arranged above the top side of the semiconductor substrate.

26. An integrated voltage clamping device according to claim 24, wherein the voltage clamping device comprises a plurality of zener diodes each with an anode terminal connected to the electrically conductive material arranged on the bottom side of the semiconductor substrate and a cathode terminal connected to the electrically conductive material arranged above the top side of the semiconductor substrate.

27. An integrated voltage clamping device according to claim 26, further comprising a plurality of resistors each having a first end connected to the electrically conductive material arranged on the bottom side of the semiconductor substrate and a second end connected to the electrically conductive material arranged above the top side of the semiconductor substrate.

28. An integrated voltage clamping device according to claim 27, wherein the plurality of resistors has a total parallel resistance of about 1 MΩ or more.
